(19) United States
(12) Patent Application Publication
(10) Pub. No.: US 2014/0077353 A1
(43) Pub. Date: Mar. 20, 2014

(54) HEAT DISSIPATING SUBSTRATE AND SEMICONDUCTOR APPARATUS EQUIPPED WITH HEAT DISSIPATING SUBSTRATE

(71) Applicant: Tadanori TAZOE, Toyota-shi (JP)

(72) Inventor: Tadanori TAZOE, Toyota-shi (JP)

(73) Assignee: TOYOTA JIDOSHA KABUSHIKI KAISHA, Toyota-shi (JP)

(21) Appl. No.: 14/021,632

(22) Filed: Sep. 9, 2013

(30) Foreign Application Priority Data
Sep. 19, 2012 (JP) 2012-205365

(51) Int. Cl. H01L 23/34

(52) U.S. Cl. CPC H01L 23/34
USPC 257/706

(57) ABSTRACT

A heat dissipating substrate is joined to a semiconductor substrate via a solder layer. The heat dissipating substrate includes an electrical insulation layer, and a junction layer that is joined to the solder layer. A surface of the junction layer which is joined to the solder layer has a plurality of protruding portions that are arranged and spaced from each other, and a recess portion partially surrounded by walls of two or more adjacent protruding portions. A straight line that passes through an arbitrary point located in the recess portion flanked by the walls of the two or more adjacent protruding portions passes through at least one protruding portion.

### INCORPORATION BY REFERENCE

The disclosure of Japanese Patent Application No. 2012-205365 filed on Sep. 19, 2012 including the specification, drawings and abstract is incorporated herein by reference in its entirety.

### BACKGROUND OF THE INVENTION

1. Field of the Invention

The invention relates to a heat dissipating substrate and a semiconductor apparatus equipped with the heat dissipating substrate.

2. Description of Related Art

A heat dissipating substrate in which an electrical insulation layer is sandwiched between a metal substrate and a junction layer has been proposed as a heat dissipating substrate that is joined with a semiconductor substrate for use. The junction layer and the semiconductor substrate are joined via a solder layer. Japanese Patent Application Publication No. 2011-222551 (JP 2011-222551 A) describes that in order to improve the heat conductivity of a heat dissipating substrate, protrusions and recesses alternating with each other in a stripe pattern are formed on a surface of an electrical insulation layer of the heat dissipating substrate to increase the surface area of the electrical insulation layer. Furthermore, Japanese Patent Application Publication No. 2009-94135 (JP 2009-94135 A) describes that the junction surface of a junction layer to a solder layer for junction with a semiconductor substrate is provided with semi-spherical recess portions so that the semiconductor substrate will not be shifted in position relative to the heat dissipating substrate when the semiconductor substrate and the heat dissipating substrate are joined via the solder layer.

The inventors of this application have considered the configuration of the junction surface of the junction layer to the solder layer in order to achieve good junction with the solder layer and restrain growth of crack in the junction layer. In a construction in which the junction surface is provided with protrusions and recesses in a stripe pattern as in Japanese Patent Application Publication No. 2011-222551 (JP 2011-222551 A), if crack occurs, the crack grows in the stripe direction, and therefore crack cannot be sufficiently restrained. In a construction in which the junction surface of the junction layer is provided with semi-spherical recess portions as in Japanese Patent Application Publication No. 2009-94135 (JP 2009-94135 A), since spaces are enclosed within the recess portions of the junction surface, gas that is generated at the time of junction of the junction layer with the solder layer resides within the recess portions of the junction layer and is not appropriately let out, so that good junction between the junction layer and the solder layer cannot be achieved. Therefore, in JP 2011-222551 A and JP 2009-94135 A, it is difficult to achieve good junction of the junction layer of the heat dissipating substrate with the solder layer and restrain growth of crack in the junction layer.

### SUMMARY OF THE INVENTION

The invention provides a heat dissipating substrate that joins well with a solder layer, and that restrains growth of crack in the junction layer of the heat dissipating substrate.

A heat dissipating substrate that is joined to a semiconductor substrate via a solder layer, in accordance with a first aspect of the invention, includes: an electrical insulation layer; and a junction layer joined to the solder layer, the junction layer having, on a surface of the junction layer which is joined to the solder layer, a plurality of protruding portions that are arranged and spaced from each other and a recess portion that is partially surrounded by walls of two or more adjacent protruding portions of the protruding portions, wherein in the surface of the junction layer which is joined to the solder layer, a straight line that passes through an arbitrary point located in the recess portion passes through at least one protruding portion of the protruding portions.

A semiconductor apparatus in accordance with a second aspect of the invention includes: the heat dissipating substrate according described above; a solder layer formed on a surface of the junction layer of the heat dissipating substrate; and a semiconductor substrate joined to a surface of the solder layer.

According to the foregoing aspects of the invention, it is possible to achieve good junction of the heat dissipating substrate with the solder layer and restrain crank in the junction layer of the heat dissipating substrate.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a plan view of a semiconductor apparatus that includes a heat dissipating substrate in accordance with a first embodiment of the invention;

FIG. 2 is a sectional view taken on line II-II of FIG. 1;

FIG. 3 is a plan view showing a portion of a surface of a junction layer of the heat dissipating substrate in accordance with the first embodiment of the invention;

FIG. 4 is a plan view showing a portion of the surface of the junction layer of the heat dissipating substrate in accordance with the first embodiment of the invention;

FIG. 5 is a plan view showing a portion of the surface of the junction layer of the heat dissipating substrate in accordance with the first embodiment of the invention;

FIG. 6 is a plan view showing a portion of a surface of a junction layer of a heat dissipating substrate in accordance with a second embodiment of the invention;

FIG. 7 is a plan view showing a portion of the surface of the junction layer of the heat dissipating substrate in accordance with the second embodiment of the invention;

FIG. 8 is a plan view showing a portion of the surface of the junction layer of the heat dissipating substrate in accordance with the second embodiment of the invention;

FIG. 9 is a plan view showing a portion of the surface of the junction layer of the heat dissipating substrate in accordance with the second embodiment of the invention;

FIG. 10 is a plan view showing a portion of a surface of a junction layer of a heat dissipating substrate in accordance with a modification in the invention;

FIG. 11 is a plan view showing a portion of a surface of a junction layer of a heat dissipating substrate in accordance with another modification in the invention;

FIG. 12 is a plan view showing a portion of a surface of a junction layer of a heat dissipating substrate in accordance with a third embodiment of the invention;

FIG. 13 is a sectional view of a semiconductor apparatus that includes a heat dissipating substrate in accordance with a modification in the invention;

FIG. 14 is a sectional view of a semiconductor apparatus that includes a heat dissipating substrate in accordance with another modification in the invention; and

FIG. 15 is a plan view showing a portion of a surface of a junction layer of a heat dissipating substrate in accordance with a comparative example.

### DETAILED DESCRIPTION OF EMBODIMENTS

Hereinafter, a heat dissipating substrate that is joined to a semiconductor substrate via a solder layer, and a semiconductor apparatus equipped with the heat dissipating substrate will be described. The heat dissipating substrate includes an electrical insulation layer and a junction layer that is joined to the solder layer. Incidentally, the heat dissipating substrate may be joined to a cooler or the like.

The materials of the metal substrate and the junction layer are not particularly limited. For example, copper, aluminum, etc. may be used as the materials of the metal substrate and the junction layer. The material of the semiconductor substrate is not particularly limited. For example, silicon, silicon carbide, etc. may be used. Furthermore, the semiconductor element or elements formed in the semiconductor substrate are not particularly limited. For example, a power semiconductor apparatus in which an IGBT or the like is formed in the semiconductor substrate may employ the heat dissipating substrate of the invention.

It suffices that the heat dissipating substrate includes an electrical insulation layer and a junction layer. Concrete examples of the heat dissipating substrate that are permissible include a DBA (Direct Blazed Aluminum) substrate, a DBC (Direct Bonding Copper) substrate, a DBCA (Direct Bonding Copper Aluminum) substrate, etc. The semiconductor apparatus may have a structure (e.g., a DBA structure) in which a heat dissipating substrate (e.g., a DBA substrate) is joined to only one of the reverse surface and observe surface of the semiconductor substrate. Furthermore, the semiconductor apparatus may have a structure in which a heat dissipating substrate is joined to each of the obverse and reverse surfaces of the semiconductor apparatus (e.g., a power card structure or a T-PM (Transfer molded-Power Module) structure, etc.).

The junction layer may have, on a surface thereof that is joined to the solder layer, a metal layer (e.g., a nickel layer or the like) for junction with the solder layer.

For example, in the case of a DBA substrate, the junction layer may include an aluminum substrate layer that contacts the electrical insulation layer, and a plating layer made of nickel or the like which is formed on a surface of the aluminum substrate layer.

The junction surface of the junction layer which is joined to the solder layer has a plurality of protruding portions that are arranged at intervals (i.e., spaced from each other), and recess portions partially surrounded by walls of two or more adjacent protruding portions. Then, a straight line that passes through any given point (arbitrary point) located in a recess portion partially surrounded or flanked by walls of two or more adjacent protruding portions passes through at least one protruding portion. Furthermore, the protruding portions may be arranged so that imaginary extension of any recess portion along a substantially straight line along the surface of the junction layer through a space between any two mutually adjacent ones of the two or more adjacent protruding portions that partially surround or flank that recess portion reaches a protruding portion other than the protruding portions that partially surround or flank the recess portion.

### First Embodiment

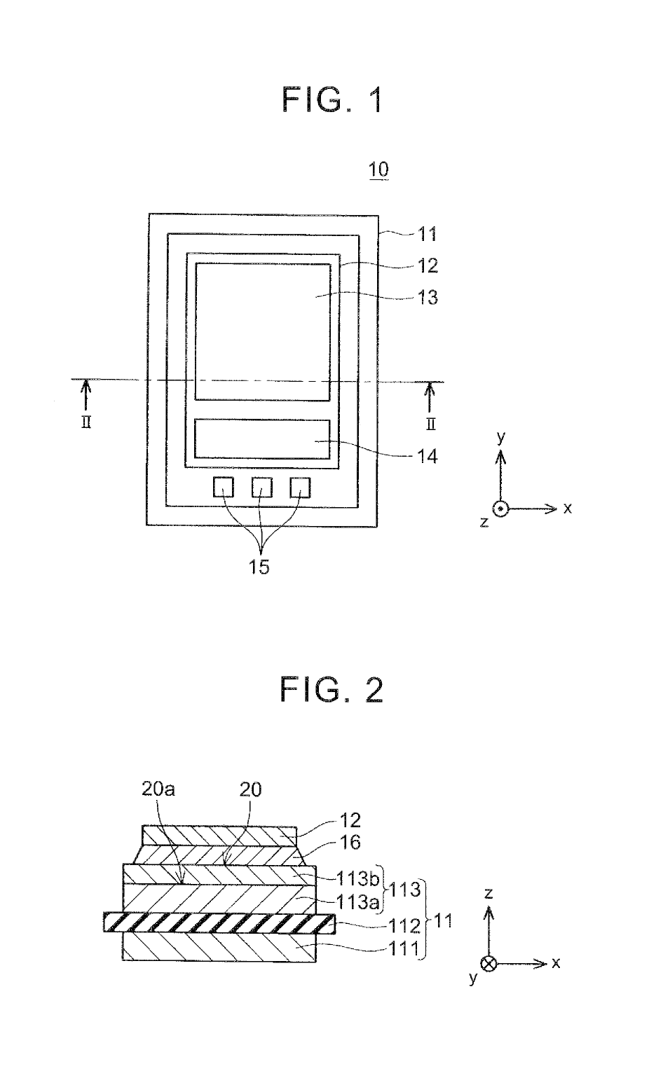

A semiconductor apparatus 10 in accordance with a first embodiment of the invention shown in FIGS. 1 and 2 includes a heat dissipating substrate 11, semiconductor substrate 12, and a solder layer 16 between the heat dissipating substrate 11 and the semiconductor substrate 12. The heat dissipating substrate 11 includes a metal substrate 111, an electrical insulation layer 112 formed on a surface of the metal substrate 111 (a surface facing in a positive direction of a z-axis), and a junction layer 113 formed on a surface of the electrical insulation layer 112. The junction layer 113 includes a substrate layer 113a that contacts the electrical insulation layer 112, and a plating layer 113b that is formed on a surface of the substrate layer 113a and that contacts the solder layer 16. The heat dissipating substrate 11 is a DBA substrate, and the metal substrate 111 and the substrate layer 113a are aluminum metal sheets, and the electrical insulation layer 112 is an aluminum nitride layer, and the plating layer 113b is a nickel plating layer.

The semiconductor substrate 12 is joined to a portion of the surface of the plating layer 113b via the solder layer 16. The semiconductor substrate 12 and the plating layer 113b are joined to each other on a junction surface 20 via the solder layer 16. In a junction surface between the substrate layer 113a and the plating layer 113b, a region on the substrate layer 113a which is located under (in the negative direction of the z-axis) the junction surface 20 of the plating layer 113b is a junction surface 20a.

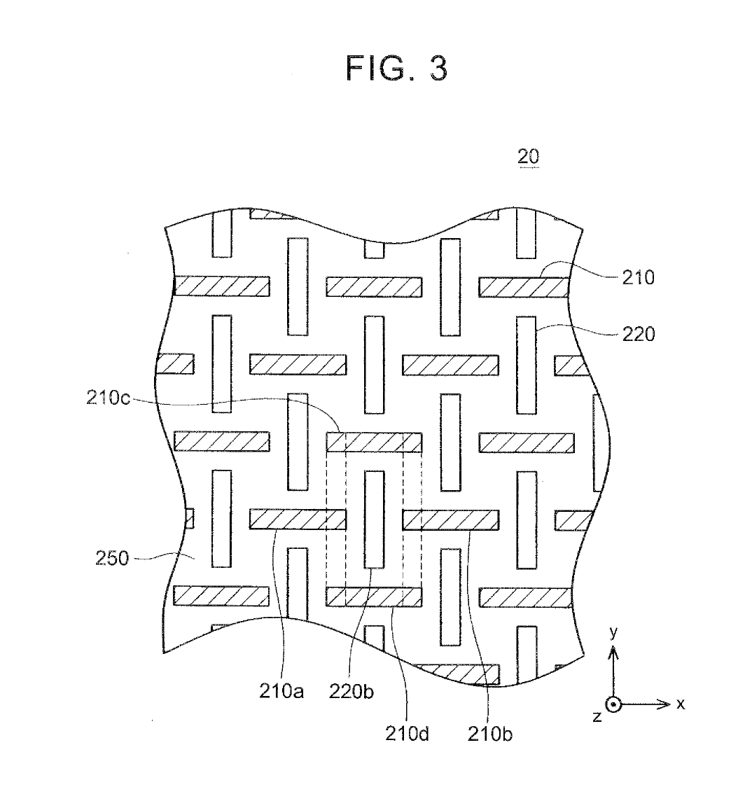

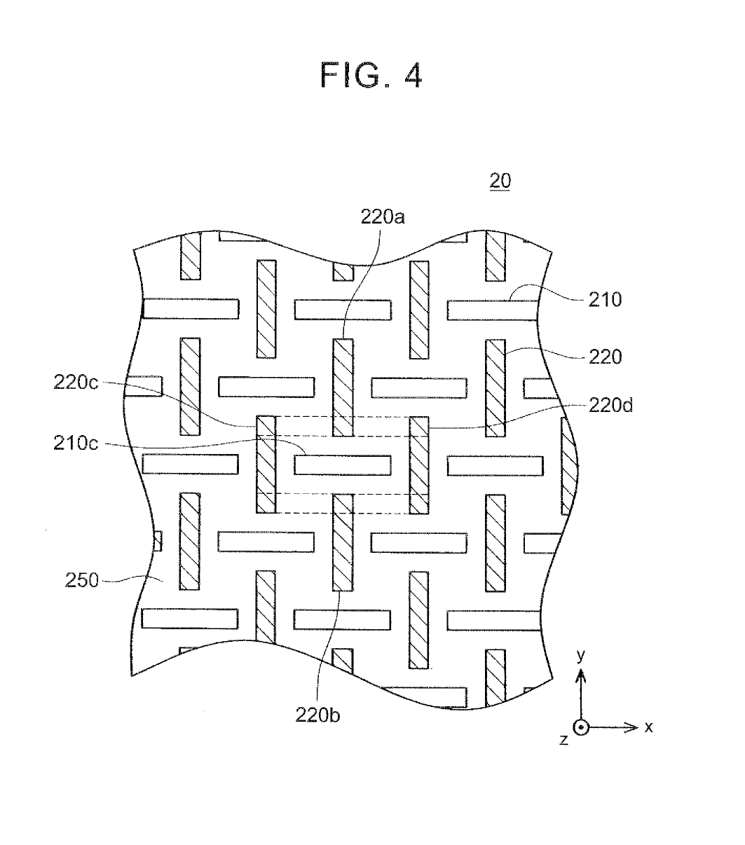

As shown in FIGS. 3 and 4, the junction surface 20 is provided with a plurality of protruding portions 210, a plurality of protruding portions 220 and a plurality of recess portions 250. Incidentally, in the surface of the plating layer 113b, a region on a peripheral edge side of the junction surface 20 is a flat surface that is at the same height as the recess portions 250. The protruding portions 210, 220 have a rectangular parallelepiped shape protruded in the positive direction of the z-axis from the recess portions 250. In a plan view, the protruding portions 210 have the shape of a rectangle of which the ratio of the length in x-directions to the length in y-directions is 5:1. In a plan view, the protruding portions 220 have the shape of a rectangle of which the ratio of the length in the x-directions to the length in the y-directions is 1:5. All of the protruding portions 210, 220 are the same in shape and size. The height of the protruding portions 210, 220 in the z-directions is sufficiently greater than the thickness of the plating layer 113b. Therefore, this configuration of the junction surface 20 can be obtained if protruding portions and recess portions arranged in substantially the same manner as the protruding portions 210, 220 and the recess portions 250 are formed on the junction surface 20a of the substrate layer 113a and then the plating layer 113b is formed on the surface of the substrate layer 113a. Incidentally, the protruding portions and the recess portions of the junction surface 20a can be formed by a method of machining or pressing the substrate layer 113a or a method of chemically etching the surface of the junction layer 113 through the use of a pattern mask.

The protruding portions 210 each have walls that extend in the x-directions along the junction surface 20 (that are walls on the long sides in a plan view and that are parallel to a zx plane), and the protruding portions 220 each have walls that extend in the y-directions along the junction surface 20 (that are walls on the long sides in a plan view and that are parallel to a yz plane). The protruding portions 210, 220 are arranged at intervals (i.e., spaced from each other) in the x-directions and the y-directions, respectively. If the length of the short sides of the protruding portions 210, 220 is defined as “1”, the interval between every two protruding portions 210 mutually adjacent in the x-directions is “3” and the interval between every two protruding portions 220 mutually adjacent in the y-directions is “3”.

As shown in FIG. 3, one protruding portion 220 is disposed between every two of the protruding portions 210 mutually adjacent in the x-directions. A given one of the protruding portions 210 overlaps, in the y-directions (i.e., in a view in a y-direction), one or more other protruding portions 210 adjacent to that one protruding portion 210 in the y-directions, by end portions thereof in the x-directions. Concretely, one protruding portion 220b is disposed between a protruding portion 210a and a protruding portion 210b that are mutually adjacent in the x-directions. Each of the protruding portions 210a, 210b overlaps, in the y-directions, other protruding portions 210c, 210d adjacent to the protruding portions 210a, 210b in the y-directions, by regions indicated by interrupted lines in FIG. 3. If the length of the short sides of the protruding portions 210, 220 is defined as “1”, the length of the end portions of the protruding portions 210 by which every two protruding portions 210 mutually adjacent in the y-directions overlap each other in the y-directions is “1”, and the interval of each one of the protruding portions 210 from a protruding portion 220 adjacent to that protruding portion 210 in the y-directions is “1”.

As shown in FIG. 4, one protruding portion 210 is disposed between every two of the protruding portions 220 mutually adjacent in the y-directions. A given one of the protruding portions 220 overlaps, in the x-directions (i.e., in a view in an x-direction), one or more other protruding portions 220 adjacent to that one protruding portion 220 in the x-directions, by portions thereof. Concretely, one protruding portion 210c, is disposed between a protruding portion 220a and a protruding portion 220b mutually adjacent in the y-directions. Each of the protruding portions 220a, 220b overlaps, in the x-directions (in a view in an x-direction), other protruding portions 220c, 220d adjacent to the protruding portions 220a, 220b in the x-directions, by regions indicated by interrupted lines in FIG. 4. If the length of the short sides of the protruding portions 210, 220 is defined as “1”, the length of the end portions of the protruding portions 220 by which every two protruding portions 220 mutually adjacent in the x-directions overlap each other in the x-directions is “1”, and the interval of each protruding portion 210 from a protruding portion 220 adjacent to that protruding portion 210 in the x-directions is “1”. The protruding portions 210, 220 formed on the junction surface 20 are arranged so that the positional relationship of the protruding portions 210a to 210d and 220a to 220d is repeated a plurality of times as an arrangement pattern. The plurality of protruding portions 210 formed on the junction surface 20 constitute a first protruding portion group as a whole, and the plurality of protruding portions 220 constitute a second protruding portion group as a whole.

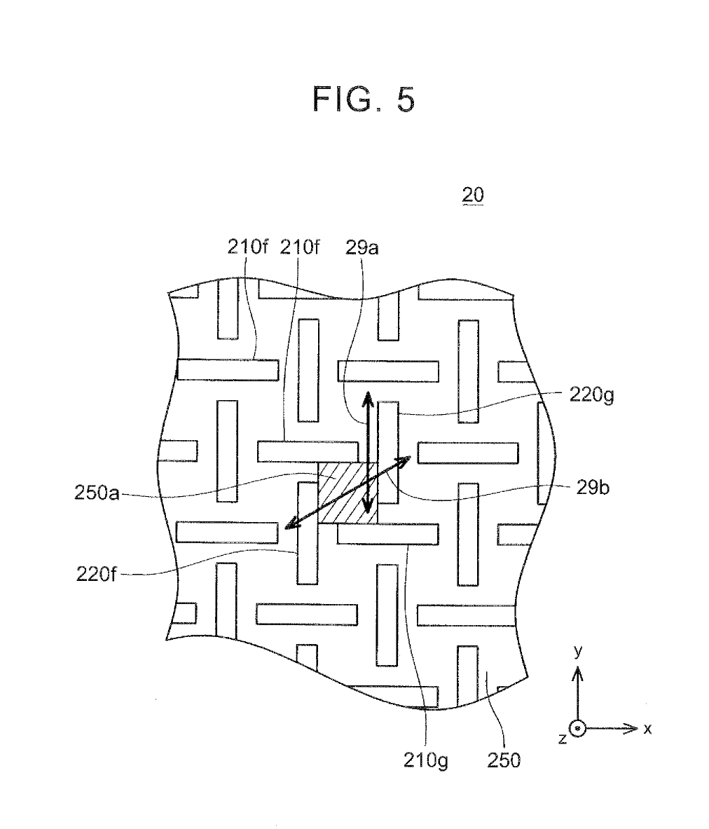

As shown in FIG. 5, a square-shaped recess portion 250a is approximately surrounded on the four sides (i.e., partially surrounded) by protruding portions 210f, 210g adjacent to the recess portion 250a in the y-directions and protruding portions 220f, 220g adjacent to the recess portion 250a in the x-directions. The recess portion 250a is open between the protruding portion 210f and the protruding portion 220f, between the protruding portion 210f and the protruding portion 220g, between the protruding portion 210g and the protruding portion 220f, and between the protruding portion 210g and the protruding portion 220g. In this arrangement of the protruding portions, another protruding portion (i.e., a protruding portion other than the protruding portions 210f, 210g, 220f, 220g) exists in each of the directions in which the recess portion 250a is open. A straight line that passes through an arbitrary point located in the recess portion 250a passes through at least one protruding portion (one of the protruding portions 210, 220). For example, a straight line passing through a point located in the recess portion 250a and extending in directions indicated by arrows 29a passes through protruding portions 220. Furthermore, for example, a straight line passing through a point located in the recess portion 250a and extending in directions indicated by arrows 29b passes through protruding portions 210, 220.

As described above, the junction surface 20 has the plurality of protruding portions 210, 220 that are arranged at intervals, and recess portions 250 each of which is partially surrounded or flanked by two or more adjacent ones of the protruding portions 210, 220. More concretely, for example, if a first direction along the junction surface 20 is an x-direction, the heat dissipating substrate 11 includes the first protruding portion group that includes the protruding portions 210 each of which has walls that extend parallel to the x-direction, and the second protruding portion group that includes the protruding portions 220 each of which has walls that extend parallel to a second direction (y-direction) perpendicular to the first direction. The protruding portions 210 of the first protruding portion group are arranged at intervals (i.e., spaced from each other) in the x-directions and arranged at intervals in the y-directions. The protruding portions 220 of the second protruding portion group are arranged at intervals in the x-directions and arranged at intervals in the y-directions. A protruding portion 220 of the second protruding portion group (e.g., the protruding portion 220b) is disposed between protruding portions 210 of the first protruding portion group that are adjacent to each other in the x-directions (more concretely, e.g., between the protruding portion 210a and the protruding portion 210b). A given one of the protruding portions 210 of the first protruding portion group (e.g., the protruding portion 210a) overlaps, in the y-directions (i.e., in a view in a y-direction), one or more other protruding portions 210 of the first protruding portion group (e.g., the protruding portions 210c, 210d) which are adjacent to that one protruding portion 210 in the y-directions, by at least portions of those protruding portions. Furthermore, a protruding portion 210 of the first protruding portion group (e.g., the protruding portion 210b) is disposed between protruding portions 220 of the second protruding portion group that are adjacent to each other in the y-directions (more concretely, e.g., between the protruding portion 220a and the protruding portion 220b). A given one of the protruding portions 220 of the second protruding portion group (e.g., the protruding portion 220a) overlaps, in the x-directions (i.e., in a view in an x-direction), one or more other protruding portions 220 of the second protruding portion group (e.g., the protruding portions 220c, 220d) which are adjacent to that one protruding portion 220 in the x-directions, by at least portions of those protruding portions.

Because the junction surface 20 has the plurality of protruding portions 210 and the plurality of protruding portions 220 as described above, it is possible to provide such an arrangement that imaginary extension of a recess portion (e.g., the recess portion 250a) along a substantially straight line along the surface of the junction layer 113 through a space between the walls of two or more protruding portions that flank the recess portion (e.g., between the wall of the protruding portion 210f and the wall of the protruding portion 220f among the protruding portions 210f, 210g, 220f, 220g which flank the recess portion 250a) reaches a protruding portion other than the protruding portions (e.g., the protruding portions 210f, 210g, 220f, 220g) that flank the recess portion (e.g., the recess portion 250a).

That is, each recess portion 250 is flanked by or sandwiched between a plurality of adjacent ones of the protruding portions 210, 220, and is open between walls of these adjacent protruding portions. Therefore, even if gas is produced when the junction surface 20 and the solder layer 16 are joined, the gas does not reside in the recess portions 250, but can be appropriately discharged, so that it is possible to join the solder layer 16 and the junction layer 113 in a good manner.

Furthermore, the protruding portions are arranged so that imaginary linear extension of each recess portion 250 in a direction in which the recess portion 250 is open reaches a protruding portion other than the two or more adjacent protruding portions that flank the recess portion. Thus, it is possible to realize such a construction that a straight line that passes through an arbitrary point located in any given one of the recess portions 250 passes through at least one protruding portion. Therefore, if crack occurs in the plating layer 113b within a recess portion 250, growth of the crack can be curbed by a protruding portion as mentioned above that is other than the protruding portions that flank the recess portion. The above-described heat dissipating substrate 11 can be joined with the solder layer 16 in a good manner, and can restrain occurrence and growth of crack in the junction layer 113. Incidentally, since the aforementioned protruding portion other than the two or more adjacent protruding portions that flank a recess portion 250 is spaced from the two or more protruding portions that flank the recess portion 250, the recess portion 250 is not closed by the protruding portion other than the two or more flanking protruding portions. In contrast, for example, in a junction surface 90 shown as a comparative example in FIG. 15 in which a substantially straight line extension from a point 99 located in a recess portion 950 (e.g., linear extension in any one of the directions of arrows 99a to 99d) does not reach any one of protruding portions 910, 920, growth of crack cannot be sufficiently restrained.

### Second Embodiment

A semiconductor apparatus in accordance with a second embodiment of the invention is different from the semiconductor apparatus 10 of the first embodiment, in that the semiconductor apparatus of the second embodiment has a junction surface 30 in place of the junction surface 20 of the semiconductor apparatus 10.

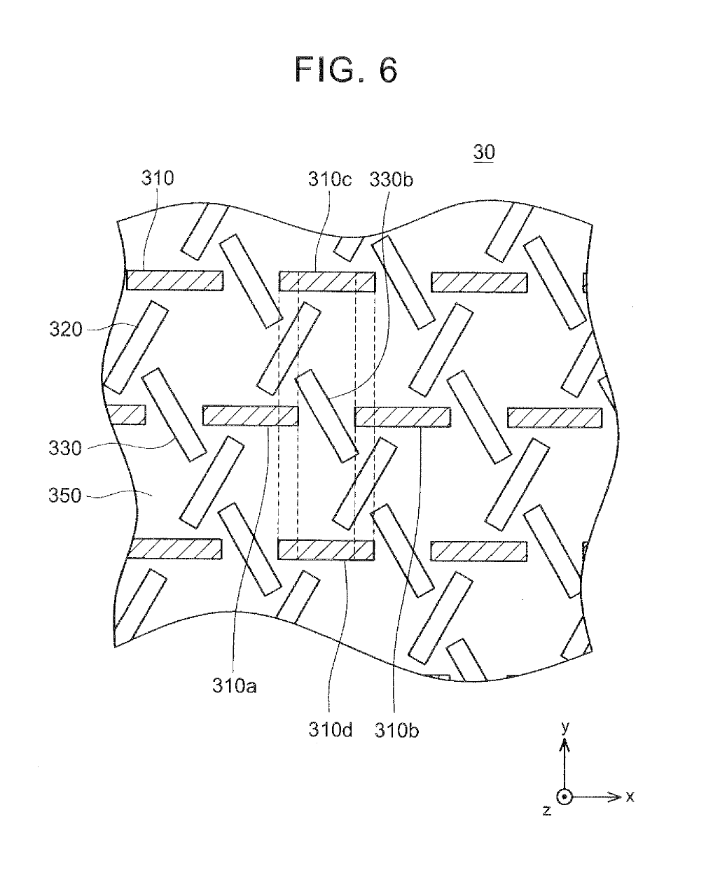

As shown in FIGS. 6 to 8, the junction surface 30 is provided with pluralities of protruding portions 310, 320, 330 and recess portions 350. The protruding portions 310, 320, 330 each have a rectangular parallelepiped shape protruded in the positive direction of the z-axis. All the protruding portions 310, 320, 330 are the same in shape and size, and have a rectangular shape in a plan view of which the ratio between the length of the long sides and the length of the short sides is 5:1.

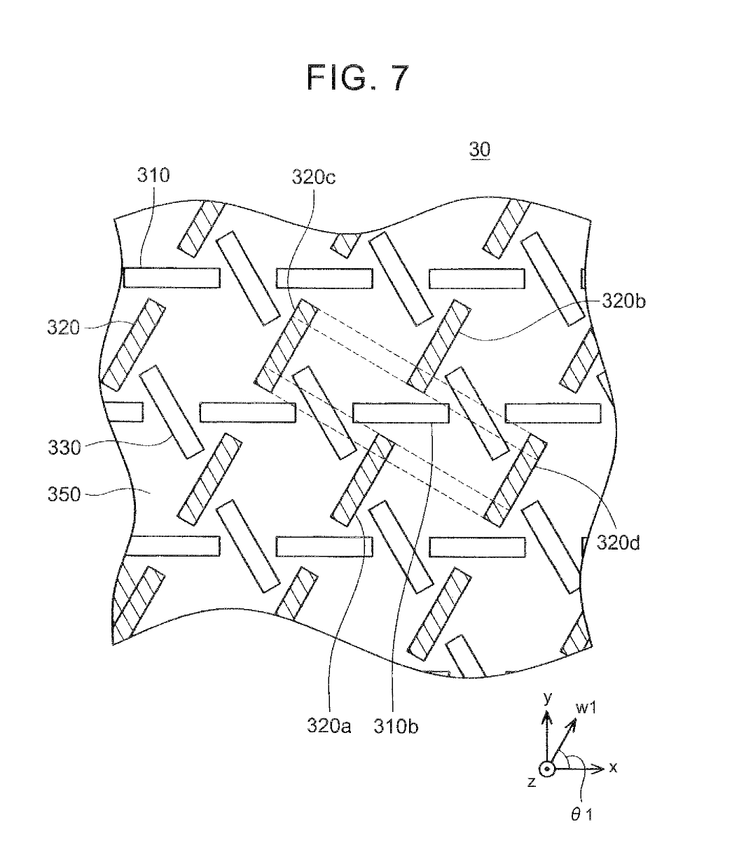

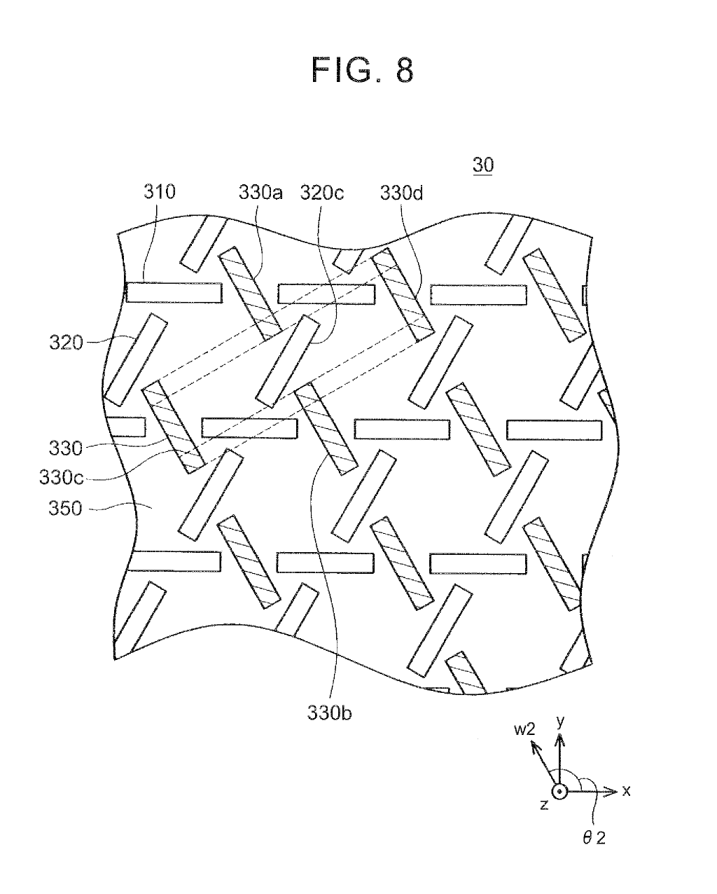

As shown in FIG. 6, the protruding portions 310 each have walls that extend parallel to x-directions along the junction surface 30 (that are walls on the long sides in a plan view and that are parallel to a zx plane). As shown in FIG. 7, the protruding portions 320 each have walls that extend parallel to w1-directions at an angle θ1=60° to the x-directions (that are walls on the long sides of the rectangular shape in a plan view and that are parallel to a zw1 plane). As shown in FIG. 8, the protruding portions 330 each have walls that extend parallel to w2-directions at an angle θ2=120° to the x-directions (that are walls on the long sides of the rectangular shape in a plan view and that are parallel to a zw2 plane). The protruding portions 310, 320, 330 are arranged at intervals in the x-directions, the w1-directions and the w2-directions, respectively, and arranged at intervals in directions orthogonal to the x-directions, the w1-directions and the w2-directions, respectively.

As shown in FIG. 6, one protruding portion 330 is disposed between every two of the protruding portions 310 mutually adjacent in the x-directions. A given one of the protruding portions 310 overlaps, in the y-directions (i.e., in a view in a y-direction), one or more other protruding portions 310 adjacent to that one protruding portion 310 in the y-directions, by at least portions of those protruding portions. Concretely, one protruding portion 330b is disposed between a protruding portion 310a and a protruding portion 310b that are mutually adjacent in the x-directions. The protruding portion 310a overlaps, in the y-directions, other protruding portions 310c, 310d adjacent to the protruding portion 310a in the y-directions, by regions indicated by interrupted lines in FIG. 7.

As shown in FIG. 7, one protruding portion 310 is disposed between every two of the protruding portions 320 mutually adjacent in the w1-directions. A given one of the protruding portions 320 overlaps, in directions orthogonal to the w1-directions (termed the “w3-directions”), one or more other protruding portions 220 adjacent to that one protruding portion 320 in the w1-directions, by at least portions of those protruding portions. Concretely, one protruding portion 310b is disposed between a protruding portion 320a and a protruding portion 320b mutually adjacent in the w1-directions. The protruding portion 320a overlaps, in the w3-directions (in a view in a w3-direction), other protruding portions 320c, 320d adjacent to the protruding portion 320a in the w3-directions, by regions indicated by interrupted lines in FIG. 7.

As shown in FIG. 8, one protruding portion 320 is disposed between every two of the protruding portions 330 mutually adjacent in the w2-directions. A given one of the protruding portions 330 overlaps, in directions orthogonal to the w2-directions (termed the w4-directions), one or more other protruding portions 330 adjacent to that one protruding portion 330 in the w4-directions, by at least portions of those protruding portions. Concretely, one protruding portion 320b is disposed between a protruding portion 330a and a protruding portion 330b that are mutually adjacent in the w2-directions. The protruding portion 330a overlaps, in the w4-directions, other protruding portions 330c, 330d adjacent to the protruding portion 330a in the w4-directions, by regions indicated by interrupted lines in FIG. 7.

The protruding portions 310, 320, 330 formed on the junction surface 30 are arranged so that the positional relationship of the protruding portions 310a to 310d, 320a to 320d, 310a to 310d is repeated a plurality of times as an arrangement pattern. The plurality of protruding portions 310 formed on the junction surface 30 constitute a first protruding portion group as a whole. Likewise, the pluralities of protruding portions 320, 330 formed on the junction surface 30 constitute a second protruding portion group and a third protruding portion group, respectively, as a whole.

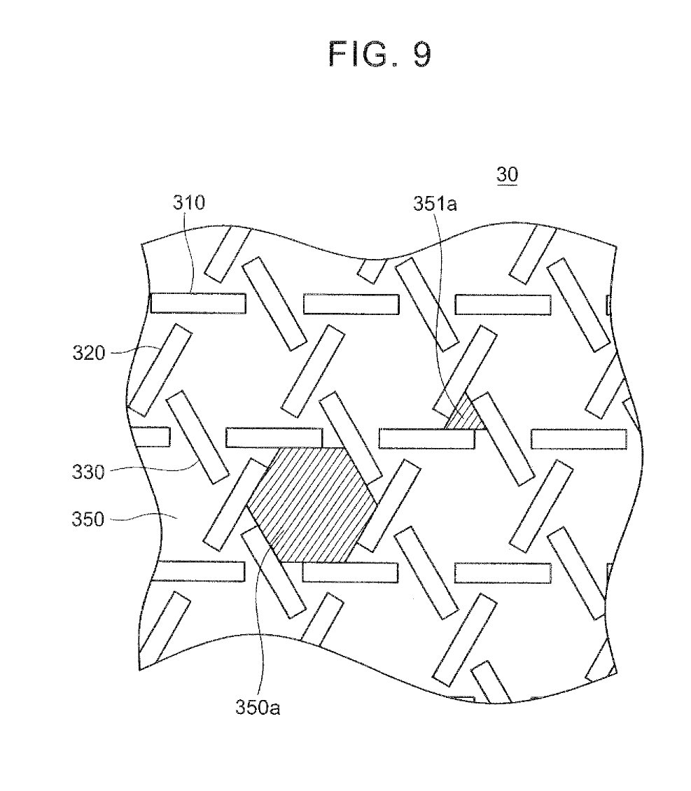

As shown in FIG. 9, the junction surface 30 is provided with regular hexagonal recess portions (e.g., a recess portion 350a) and regular triangle recess portions (e.g., a recess portion 351a). For example, the recess portions 350a, 351a are approximately surrounded or flanked (i.e., partially surrounded) by protruding portions 310, 320, 330 that are adjacent to each other. The recess portion 350a is open between every two mutually adjacent ones of the six surrounding or flanking protruding portions 310, 320, 330. The protruding portions are arranged so that imaginary linear extension of the recess portion 350a in any one of the directions in which the recess portion 350a is open reaches a protruding portion that is other than the protruding portions that surround or flank the recess portion 350a. Thus, a construction is provided such that a straight line that passes through an arbitrary point located in the recess portion 350a passes through at least one protruding portion. Likewise, the recess portion 351a is open between every two mutually adjacent ones of the three surrounding or flanking protruding portions 310, 320, 330. The protruding portions are arranged so that imaginary linear extension of the recess portion 351a in any one of the directions in which the recess portion 351a is open reaches a protruding portion other than the protruding portions that surround or flank the recess portion 351a. Thus, a construction is provided such that a straight line that passes through an arbitrary point located in the recess portion 351a passes through at least one protruding portion.

The heat dissipating substrate described above includes three protruding portion groups (a first protruding portion group made up of the protruding portions 310, a second protruding portion group made up of the protruding portions 320 and a third protruding portion group made up of the protruding portions 330). Each of the protruding portions 310, 320 or 330 of each protruding portion group has walls whose longitudinal directions (the x-directions, the w1-directions or the w2-directions, respectively) extend parallel to each other along the surface of the junction layer 113. The protruding portions 310, 320 or 330 of each group are arranged at intervals in directions parallel to the longitudinal directions of the aforementioned walls, and also arranged at intervals in directions perpendicular to the longitudinal directions of the walls. The longitudinal directions of the aforementioned walls (that are, e.g., the x-directions) of the protruding portions (e.g., the protruding portion 310) of a given protruding portion group (e.g., the first protruding portion group) are directions that intersect the longitudinal directions of the walls (that are, e.g., the w1 and w2-directions) of the protruding portions (e.g., the protruding portions 320 and 330) of the other protruding portion group (e.g., the second protruding portion group and the third protruding portion group). A given one of the protruding portions (e.g., the protruding portions 310a, 320a or 330a) of each protruding portion group overlaps, in the directions perpendicular to the longitudinal directions of the walls of that one protruding portion (in a view in one of the directions perpendicular to the longitudinal directions), one or more other protruding portions adjacent to that one protruding portion in the directions perpendicular to the longitudinal directions (e.g., the protruding portions 310c and 310d, the protruding portions 320c and 320d or the protruding portions 330c and 330d), by at least portions of those protruding portions. Every two of the protruding portions of a given protruding portion group which are mutually adjacent in the longitudinal directions of the aforementioned walls (e.g., the protruding portion 310a and the protruding portion 310b) have a protruding portion of another protruding portion group (e.g., the protruding portion 330b) disposed therebetween.

Because the junction surface 30 has the protruding portions 310, 320, 330 as described above, it is possible to realize an arrangement of the protruding portions such that imaginary extension of a given recess portion 350 along a substantially straight line along the junction surface 30 through a space between the walls of two mutually adjacent ones of the two or more protruding portions that partially surround or flank that recess portion 350 reaches a protruding portion other than the protruding portions surrounding or flanking the recess portion 350. Therefore, as in the first embodiment, even if gas is produced when the junction surface 30 and the solder layer 16 are joined, the gas does not reside in the recess portions 350, but can be appropriately discharged, so that it is possible to join the solder layer 16 and the junction layer 113 in a good manner. Furthermore, due to the arrangement of the protruding portions such that imaginary linear extension of any given recess portion 350 in a direction in which that recess portion 350 is open reaches a protruding portion (a protruding portion 310, 320 or 330) apart from the recess portion 350, if crack occurs in a recess portion 350, growth of the crack is restrained by such a protruding portion apart from that recess portion 350.

### Modification

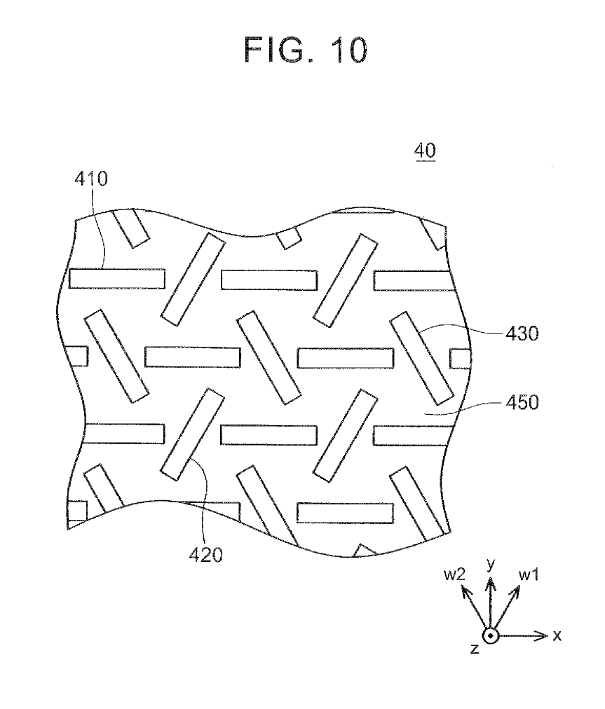

The arrangement of the protruding portions in which the directions of the aforementioned walls of the protruding portions are the directions of three or more straight lines in a plane that intersect one another is not limited to the arrangement of the second embodiment. For example, it is permissible to adopt a construction of a junction surface
shown in FIG. 10 which has protruding portions 410, 420, 430 whose long-side walls extend in the directions of three straight lines, respectively, along the surface 40 that intersect one another and triangular recess portions 450 approximately surrounded by mutually adjacent protruding portions 410, 420, 430. Incidentally, the arrangement of the protruding portions 410, 420, 430 shown in FIG. 10 can be obtained by turning the protruding portions 220 in the arrangement shown in FIG. 3 about the centers of their rectangular bodies so that the long sides of the protruding portions 220 in every other row extending in the y-directions lie in the w1-directions and the long sides of the protruding portions 220 in the other set of every other row extending in the y-directions lie in the w2-directions. The long-side walls (also simply termed the walls in this specification) of the protruding portions 410 extend in the x-directions, the long-side walls of the protruding portions 420 extend in the w1-directions, and the long-side walls of the protruding portions 430 extend in the w2-directions.

Furthermore, the shape of the protruding portions in a plan view is not limited to the rectangular shape in accordance with the first and second embodiments. For example, the protruding portions may be, for example, the protruding portions provided on a junction surface 50 shown in FIG. 11, that is, protruding portions 510 whose shape in a plan view is elliptical, and protruding portions 520 whose shape in a plan view is an arc shape. The longitudinal directions of the walls of the protruding portions 510 extend in the x-directions. The longitudinal directions of the walls of the protruding portions 520 extend in the y-directions. The protruding portions 510 and the protruding portions 520 are arranged in substantially the same positional relationship as the protruding portions 210 and the protruding portions 220 in the first embodiment. Furthermore, as shown in FIG. 11, the shapes of the protruding portions in a plan view may differ from one protruding portion group to another. Still further, a single protruding portion group may include protruding portions of different shapes in a plan view as long as the longitudinal directions of the walls thereof coincide with each other.

### Third Embodiment

A semiconductor apparatus in accordance with a third embodiment of the invention is different from the semiconductor apparatus 10 of the first embodiment in that the semiconductor apparatus of the third embodiment has a junction surface 60 in place of the junction surface 20.

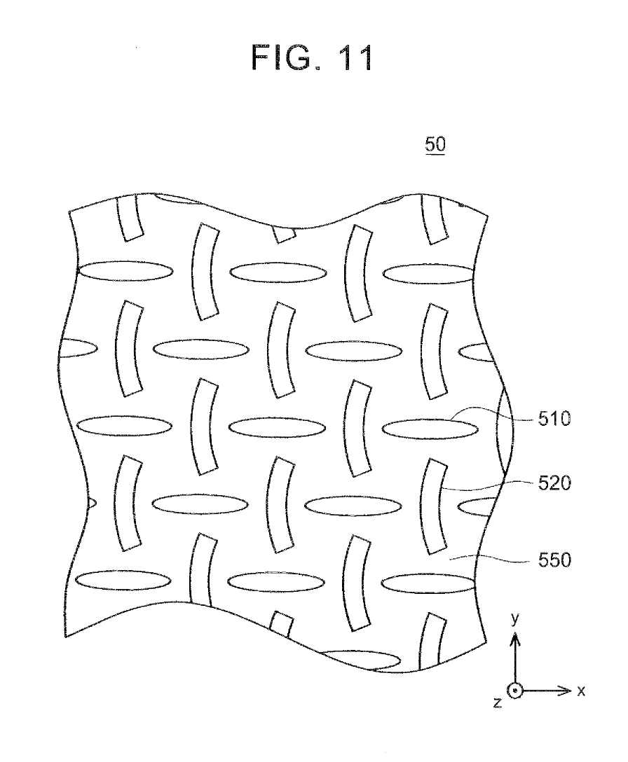

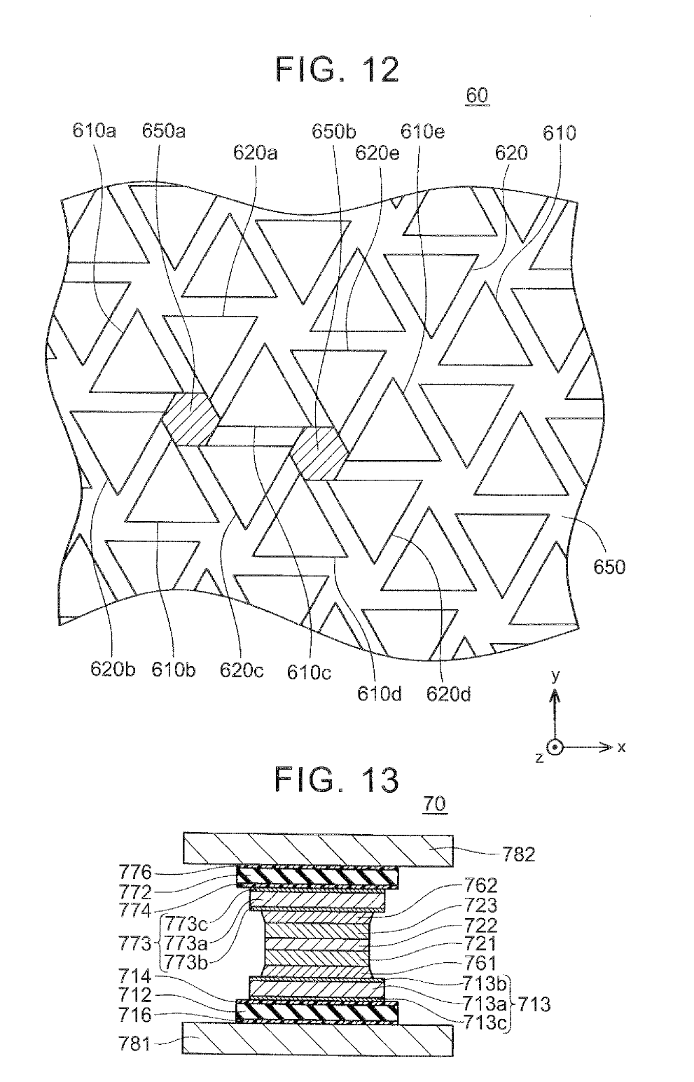

As shown in FIG. 12, the junction surface 60 is provided with pluralities of regular triangular protruding portions 610, 620. The protruding portions 610 each have a base parallel to an x-axis and a corresponding vertex angle whose apex faces in the positive direction of a y-axis. The protruding portions 620 each have a base parallel to the x-axis and a corresponding vertex angle whose apex faces in the negative direction of the y-axis. Each of the protruding portions 610 is adjacent to one or more of the protruding portions 620. Recess portions 650 include regular hexagonal portions (e.g., recess portions 650a, 650b) approximately surrounded or flanked by three protruding portions 610 and three protruding portions 620 that are adjacent to each other.

Concretely, the recess portion 650a is approximately surrounded or flanked by protruding portions 610a to 610c and protruding portions 620a to 620c, and the recess portion 650b is approximately surrounded or flanked by protruding portions 610c to 610e and protruding portions 620c to 620e. Furthermore, each of the recess portions 650a, 650b is open between a protruding portion 610 and a protruding portion 620 that are mutually adjacent among the protruding portions 610 and 620 that surround or flank the recess portion 650, and the protruding portions 610, 620 are arranged so that imaginary linear extension of either one of the recess portions 650a, 650b in a direction in which the recess portion 650a or 650b is open reaches a protruding portion other than the protruding portions that surround or flank the recess portion 650a or 650b. Thus, the junction surface 60 is constructed so that a straight line that passes through an arbitrary point located in either one of the recess portions 650a, 650b passes through at least one protruding portion.

For example, the recess portion 650a is open between the protruding portion 610c and the protruding portion 620c that are adjacent to each other, and a protruding portion 620e that does not flank the recess portion 650a exists in an imaginary extension of the recess portion 650a along a substantially straight line in the direction in which the recess portion 650a is open. The recess portion 650a and the protruding portions 610c to 610e and the protruding portions 620c to 620e that partially surround the recess portion 650a maintain the same positional relationship if they are turned by 60° at a time about the center of the hexagonal shape of the recess portion 650a. Therefore, it can be understood that a protruding portion that does not flank the recess portion 650a exists in an imaginary extension of the recess portion 650a along a substantially straight line in any one of the six directions in which the recess portion 650a is open. Furthermore, the positional relationship among the recess portion 650b and the protruding portions 610c to 610e and the protruding portions 620e to 620e that surround the recess portion 650b is the same as the positional relationship among the recess portion 650a and the protruding portions 610c to 610e and the protruding portions 620c to 620e that surround the recess portion 650a. Therefore, it can be likewise understood that a protruding portion that does not flank the recess portion 650b exists in an imaginary extension of the recess portion 650b along a substantially straight line in any one of the six directions in which the recess portion 650b is open. The protruding portions 610, 620 formed on the junction surface 60 are arranged so that the positional relationship among the protruding portions 610a to 610e, 620a to 620e is repeated as a pattern a plurality of times.

Because the junction surface 60 has the protruding portions 610, 620 as described above, it is possible to realize an arrangement of the protruding portions such that a protruding portion other than the protruding portions that surround a given one of the recess portions 650 exists in an imaginary extension of that one recess portion 650 along a substantially straight line extending along the surface of the junction surface 60 through a space between the walls of two mutually adjacent protruding portions of the two or more protruding portions that surround or flank that recess portion 650. Therefore, as in the first embodiment and the like, even if gas is produced when the junction surface 60 and the solder layer 16 are joined, the gas does not reside in the recess portions 650, but can be appropriately discharged, so that it is possible to join the solder layer 16 and the junction layer 113 in a good manner. Furthermore, due to the arrangement of the protruding portions such that imaginary linear extension of any given recess portion 650 in a direction in which that recess portion 650 is open reaches a protruding portion apart from the recess portion 650, if crack occurs in a recess portion 650, growth of the crack is restrained by such a protruding portion apart from that recess portion 650.

Incidentally, the shapes of the protruding portions whose longitudinal directions in a plan view of the surface of the junction layer cannot be defined as in the third embodiment are not limited to a regular triangle but may also be other polygonal shapes such as a regular hexagonal shape.

Although in conjunction with the foregoing embodiments, the semiconductor apparatuses having a DBA structure are illustrated, this is not restrictive. For example, a semiconductor apparatus 70 that has a power card structure as shown in FIG. 13 is permissible. The semiconductor apparatus 70 includes a semiconductor substrate 721, a metal electrode 723 made of copper and joined to an obverse surface of the semiconductor substrate 721 via a solder layer 722, and a plurality of heat dissipating substrates. The heat dissipating substrate joined to the reverse surface side of the semiconductor substrate 721 via a solder layer 761 includes a junction layer 713, a grease layer 714 and an electrical insulation layer 712 that are stacked in that order from the semiconductor substrate 721 side. The heat dissipating substrate joined to the metal electrode 723 on the obverse surface side of the semiconductor substrate 721 via a solder layer 762 includes a junction layer 773, a grease layer 774 and an electrical insulation layer 772 that are stacked in that order from the semiconductor substrate 721 side. The electrical insulation layers 712, 772 are electrically insulative ceramic plates, and are joined to coolers 781 and 782 via the grease layers 716, 776, respectively. The junction layer 713 includes a metal substrate 713a made of copper, and nickel plating layers 713b, 713c formed on the obverse and reverse surfaces of the metal substrate 713a. The junction layer 773 includes a metal substrate 773a made of copper, and nickel plating layers 773b, 773c formed on the obverse and reverse surfaces of the metal substrate 773a. If the obverse surface of the metal substrate 713a (a plating layer 713b-side surface thereof) is provided with protruding portions and recess portions as described above in conjunction with the embodiments, and is subjected to nickel plating, the obverse surface of the plating layer 713b (the junction surface of the junction layer 713 to the solder layer 761) can be provided with substantially the same protruding portions and recess portions. Likewise, if the reverse surface of the metal substrate 713a (a plating layer 773b-side surface thereof) is provided with protruding portions and recess portions, and is subjected to nickel plating, the obverse surface of the plating layer 773b (the junction surface of the junction layer 773 to the solder layer 762) can be provided with substantially the same protruding portions and recess portions. A portion of the semiconductor apparatus 70 extending from the junction layer 773 to the junction layer 713 is covered with a mold resin. According to the semiconductor apparatus 70, the coolers 781, 782 are joined to the obverse surface side and the reverse surface side of the semiconductor substrate 721, so that heat can efficiently be removed from the semiconductor substrate 721.

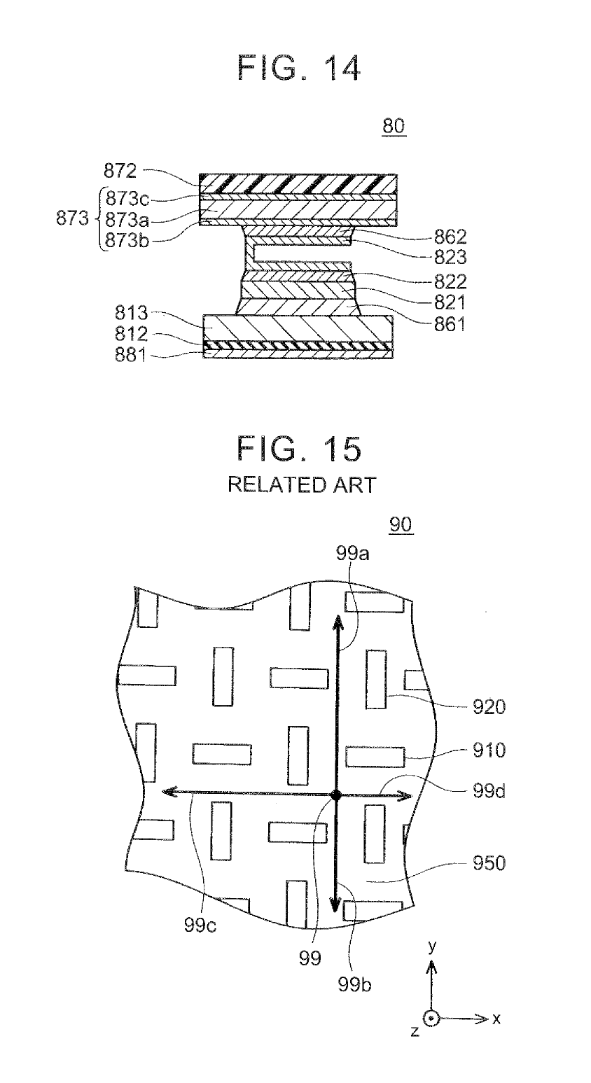

Furthermore, for example, a semiconductor apparatus 80 that has a T-PM structure as shown in FIG. 14 may also be permissible. The semiconductor apparatus 80 includes a semiconductor substrate 821, a metal electrode 823 made of copper and joined to the obverse surface of the semiconductor substrate 821 via a solder layer 822, and a plurality of heat dissipating substrates. The heat dissipating substrate joined to the reverse side of the semiconductor substrate 821 via the solder layer 861 includes the junction layer 813 and the electrical insulation layer 812 stacked in that order from the semiconductor substrate 821 side. The heat dissipating substrate joined to the metal electrode 823 disposed on the obverse side of the semiconductor substrate 821 via a solder layer 862 has a junction layer 873 and an electrical insulation layer 872 made of resin. The electrical insulation layer 812 is formed from a sheet-shaped electrical insulation member, and a heat dissipating sheet 881 made of copper. The junction layer 813 may be made of copper, and a junction surface of the junction layer 813 to the solder layer 861 may be provided with protruding portions and recess portions as described above in conjunction with the embodiments. The junction layer 873 includes a metal substrate 873a made of copper, and nickel plating layers 873b, 873c formed on the obverse and reverse surfaces of the metal substrate 873a. If a reverse surface of the metal substrate 873a (a plating layer 873b-side surface thereof) is provided with protruding portions and recess portions, and then is subjected to nickel, plating, the obverse surface of the plating layer 873b (the junction surface of the junction layer 873 to the solder layer 862) can be provided with substantially the same protruding portions and recess portions. A portion of the semiconductor apparatus 80 extending from the electrical insulation layer 872 to the electrical insulation layer 812 is covered with a mold resin.

While the embodiments of the invention have been described in detail above, these embodiments are merely illustrative, and do not restrict the claims. The arts described in the claims include various modifications and changes of the concrete examples illustrated above.

The technical elements described or illustrated in the specification or the drawings achieve their technical usefulness individually or in various combinations thereof. Furthermore, the arts illustrated in the specification or the drawings are able to simultaneously accomplish a plurality of objects, and have technical usefulness merely by accomplishing one of the objects.

What is claimed is:

1. A heat dissipating substrate that is joined to a semiconductor substrate via a solder layer, the heat dissipating substrate comprising:
an electrical insulation layer; and
a junction layer joined to the solder layer, the junction layer having, on a surface of the junction layer which is joined to the solder layer, a plurality of protruding portions that are arranged and spaced from each other and a recess portion that is partially surrounded by walls of two or more adjacent protruding portions of the protruding portions,
wherein in the surface of the junction layer which is joined to the solder layer, a straight line that passes through an arbitrary point located in the recess portion passes through at least one protruding portion of the protruding portions.

2. The heat dissipating substrate according to claim 1, wherein:
the protruding portions include at least two protruding portion groups each of which includes a plurality of protruding portions of the protruding portions;
each of the protruding portions has walls whose longitudinal direction extend parallel to each other along the surface of the junction layer;
the protruding portions are arranged and spaced from each other in the longitudinal directions of the walls, and are arranged and spaced from each other in a direction perpendicular to the longitudinal direction of the walls;
the longitudinal directions of the walls of the protruding portions included in one protruding portion group of the protruding portion groups intersects the longitudinal direction of the walls of the protruding portions included in another protruding portion group of the protruding portion groups;
one protruding portion of each protruding portion group at least partially overlaps, in the direction perpendicular to the longitudinal direction of the walls of the one protruding portion, another protruding portion of the same protruding portion group which is adjacent to the one protruding portion in the direction perpendicular to the longitudinal direction of the walls; and
a protruding portion of the other protruding portion group is disposed between protruding portions of the one protruding portion group which are mutually adjacent in the longitudinal direction of the walls.

3. The heat dissipating substrate according to claim 1, wherein:
the protruding portions include a first protruding portion group that includes a plurality of protruding portions each of which has a wall that extends parallel to a first direction along the surface of the junction layer, and a second protruding portion group that includes a plurality of protruding portions each of which has a wall that extends parallel to a second direction that is perpendicular to the first direction;
the plurality of protruding portions of the first protruding portion group are arranged and spaced from each other in the first direction, and are arranged and spaced from each order in the second direction;
the plurality of protruding portions of the second protruding portion group are arranged and spaced from each other in the first direction, and are arranged and spaced from each other in the second direction;
a protruding portion of the second protruding portion group is disposed between protruding portions of the first protruding portion group which are mutually adjacent in the first direction;
one protruding portion of the first protruding portion group at least partially overlaps, in the second direction, another protruding portion of the first protruding portion group which is adjacent to the one protruding portion in the second direction;
a protruding portion of the first protruding portion group is disposed between protruding portions of the second protruding portion group which are mutually adjacent in the second direction; and
one protruding portion of the second protruding portion group at least partially overlaps, in the first direction, another protruding portion of the second protruding portion group which is adjacent to the one protruding portion in the first direction.

4. The heat dissipating substrate according to claim 1, wherein:
the protruding portions include at least a plurality of a first protruding portions included in a first protruding portion group and a plurality of a second protruding portions included in a second protruding portion group;
each of the first protruding portions has walls whose a first longitudinal direction extend parallel to each other along the surface of the junction layer;
each of the second protruding portions has walls whose a second longitudinal direction extend parallel to each other along the surface of the junction layer;
the first longitudinal direction intersects with the second longitudinal direction;
the first protruding portions are arranged and spaced from each other in the first longitudinal direction of the walls, and are arranged and spaced from each other in a direction perpendicular to the first longitudinal direction;
the second protruding portions are arranged and spaced from each other in the second longitudinal direction of the walls, and are arranged and spaced from each other in a direction perpendicular to the second longitudinal direction;
the first protruding portion at least partially overlaps, in the direction perpendicular to the first longitudinal direction, with another protruding portion of the first protruding portion group which is adjacent to the one protruding portion in the direction perpendicular to the first longitudinal direction;
the second protruding portion at least partially overlaps, in the direction perpendicular to the second longitudinal direction, with another protruding portion of the second protruding portion group which is adjacent to the one protruding portion in the direction perpendicular to the second longitudinal direction; and
the second protruding portion is disposed between the first protruding portions which are mutually adjacent in the first longitudinal direction.

5. A semiconductor apparatus comprising:
the heat dissipating substrate according to claim 1;
a solder layer formed on a surface of the junction layer of the heat dissipating substrate; and
a semiconductor substrate joined to a surface of the solder layer.
